(19) United States
(12) Patent Application Publication
(10) Pub. No.: US 2026/0182237 A1
(43) Pub. Date: Jun. 25, 2026

(54) Display Device and Method for Fabricating Display Device

(71) Applicant: Samsung Display Co., Ltd., Yongin-si (KR)

(72) Inventors: Hyun Ho Jeong, Yongin-si (KR); Tae Hee Kim, Yongin-si (KR); Jong Seok Joo, Yongin-se (KR)

(73) Assignee: Samsung Display Co., Ltd., Yongin-si (KR)

(21) Appl. No.: 19/335,537

(22) Filed: Sep. 22, 2025

(30) Foreign Application Priority Data
Dec. 23, 2024 (KR) 10-2024-0193589

(51) Int. Cl. H10K 71/80; H10K 59/12; H10K 59/80

(52) U.S. Cl. CPC H10K 71/80; H10K 59/1201; H10K 59/873

(57) ABSTRACT

A method of manufacturing a display device is provided. The method includes: forming a separator on a first surface of a substrate; loading the substrate on a plate such that the plate faces the first surface of the substrate; depositing a deposition material on a second surface of the substrate, the second surface being opposite the first surface; separating the substrate from the plate; and cleaning the substrate to remove the separator. In this method, the separator includes a polymer resin having carboxyl functional groups or hydroxyl functional groups.

This application claims priority from Korean Patent Application No. 10-2024-0193589 filed on Dec. 23, 2024, the disclosure of which is incorporated by reference herein in its entirety.

### TECHNICAL FIELD

The present disclosure relates to a display device and a method for fabricating a display device.

### BACKGROUND

As our information-oriented society evolves, demands for improvements to display devices are ever increasing. Contemporary display devices may be flat-panel display devices such as a liquid-crystal display device, a field emission display device, and a light-emitting display device. Light-emitting display devices may include an organic light-emitting display device including organic light-emitting emitting diodes as light-emitting elements, or a light-emitting diode display device including inorganic light-emitting diodes such as light-emitting diodes (LEDs) as light-emitting elements.

A display device may include a display module, e.g., a display panel that includes light-emitting elements to emit light, and a window member that is disposed on an upper surface of the display module to protect the upper surface of the display module. The window member may be made of glass. In order to output light evenly from the display module, it is desirable to have a display device where a first surface of the window member that faces the display module and a second surface of the window member opposite the first surface are flat. However, during manufacture of the display device, depositing of a high-temperature deposition material on the surface of the window member may cause warping of the window member due to a temperature difference between the first surface of the window member facing the display module and the second surface of the window member opposite the first.

Accordingly, a need exists for improved methods of fabricating display devices to have smooth surfaces on a window member of the display device and similarly to have resultant display devices with such characteristics.

### BRIEF SUMMARY

Aspects of the present disclosure provide a display device capable of preventing warping and/or other irregular deformation of a window member by reducing a temperature difference between opposing surfaces of the window member when a deposition material is deposited on the window member at a high temperature.

It should be appreciated that the objects of the present disclosure are not limited to the above-mentioned object and that other objects of the present disclosure will be apparent to those skilled in the art from the remainder of the present disclosure.

According to an aspect of the present disclosure, there is provided a method for manufacturing a display device. In some embodiments, the method includes forming a separator on a first surface of a substrate; loading the substrate on a plate such that the plate faces the first surface of the substrate; depositing a deposition material on a second surface of the substrate, the second surface being opposite the first surface; separating the substrate from the plate; and cleaning the substrate to remove the separator from the substrate, wherein the separator includes a polymer resin having carboxyl functional groups or hydroxyl functional groups.

In some examples, a thickness of the separator may be 20% or more of a thickness of the substrate.

In some examples, the thickness of the separator may be equal to or greater than 100 μm.

In some examples, an area of contact between the separator and the plate that exists prior to separating the substrate from the plate, i.e., the peeling portion may be equal to or less than 50% of a surface area of the first surface of the substrate.

In some examples, the depositing step may be carried out at a temperature of 100° C. or higher.

In some examples, the forming of the separator may include spraying a separator ink on the first surface of the substrate and curing the separator ink with ultraviolet rays to form the separator.

In some examples, the spraying of the separator ink and the curing of the separator ink with ultraviolet rays may be repeated until the thickness of the separator becomes equal to or greater than at least 20% of the thickness of the substrate.

In some examples, the substrate may be a window member of the display device, and the deposition material is an anti-reflection film of the display device or an anti-fingerprint film of the display device.

In some examples, the polymer resin having the carboxyl functional groups may include at least one of: (meth)acrylic acid, 2-(meth)acryloyloxy acetic acid, 3-(meth)acryloyloxy propyl acid, 4-(meth)acryloyloxy butyric acid, an acrylic acid dimer, itaconic acid and maleic acid.

In some examples, the polymer resin having hydroxy functional groups may include at least one of: 2-hydroxyethyl (meth)acrylate, 3-hydroxypropyl (meth)acrylate, 4-hydroxybutyl (meth)acrylate, and 6-hydroxyhexyl (meth)acrylate.

In some examples, the cleaning may be performed using at least one of water and an alkaline solution.

In some examples, the method may include, prior to the forming of the separator, forming a black mark on the first surface of the substrate adjacent to an edge of the first surface of the substrate. In these examples, the separator may be formed on the black mark.

In some examples, the forming of the separator may include: forming a first separator on the first surface of the substrate; and forming a second separator on the first surface such that the second separator is spaced apart from the first separator.

In some examples, the forming of the separator may include: simultaneously forming a first separator and a second separator spaced apart from the first separator on the first surface of the substrate.

In some examples, the forming of the first separator and the second separator also includes: forming the first separator such that the first separator is located adjacent to an edge on a first side of the substrate on the first surface of the substrate and extends in a first direction along the first side, and forming the second separator such that the second separator is located adjacent to an edge on a second side of the substrate on the first surface of the substrate, the second side being opposite to the first side of the substrate, and the second separator extending in the first direction along the second side, and wherein the first separator is parallel to the second separator.

In some examples, the separator may be formed on the first surface of the substrate adjacent to an edge of the first surface of the substrate.

In some examples, the first separator may be formed on the first surface of the substrate adjacent to an edge of the first surface of the substrate, and the second separator may be formed further from the edge on the first surface than the first separator such that a minimum distance between the first separator and the edge is less than a minimum distance between the second separator and the edge.

According to an aspect of the present disclosure, there is provided and electronic device. In some embodiments, the electronic device includes a display module configured to provide images and a processor configured to transmit an image data signal to the display module. The display module is fabricated by a method including: forming a separator on a first surface of a substrate; loading the substrate on a plate such that the plate faces the first surface of the substrate; depositing a deposition material on a second surface of the substrate, the second surface being opposite the first surface; separating the substrate from the plate; and cleaning the substrate to remove the separator, and wherein the separator includes a polymer resin having carboxyl groups or hydroxyl functional groups.

In some examples, a thickness of the separator may be 20% or more of a thickness of the substrate.

In some examples, the substrate may be a window member of the display module, and the deposition material may be an anti-reflection film of the display module or an anti-fingerprint film of the display module.

Specific details of other embodiments are included in the detailed description and drawings.

According to embodiments of the present disclosure, it is possible to maintain the flatness of a substrate when a deposition material is formed on the substrate in a high-temperature thin-film deposition apparatus by forming a separator on a surface of the substrate.

In addition, after the deposition material has been deposited on the substrate, the separator can easily be removed from the substrate via a cleaning process.

It should be noted that effects of the present disclosure are not limited to those described above and other effects of the present disclosure will be apparent to those skilled in the art from the following description.

### BRIEF DESCRIPTION OF THE DRAWINGS

The above and other aspects and features of the present disclosure will become more apparent by reading the following detailed description of non-limiting embodiments thereof, and with reference to the accompanying drawings, in which:

FIG. 1 is a perspective view of a display device according to an embodiment of the present disclosure.

FIG. 2 is an exploded perspective view of a display device according to an embodiment of the present disclosure.

FIG. 3 is a side view of a display device according to an embodiment of the present disclosure.

FIG. 4 is a partial cross-sectional view of a display panel according to an embodiment of the present disclosure.

FIG. 5 is a flowchart for illustrating a method for fabricating a display device according to an embodiment of the present disclosure.

FIG. 6 is a plan view showing the substrate and the separator at step S100 of FIG. 5 according to a first embodiment of the method.

FIG. 7 is a cross-sectional view taken along line A-A′ of FIG. 6.

FIG. 8 is a plan view showing the substrate and the separator at step S100 of FIG. 5 according to a second embodiment of the method.

FIG. 9 is a plan view showing the substrate and the separator at step S100 of FIG. 5 according to a third embodiment of the method.

FIG. 10 is a cross-sectional view taken along line B-B′ of FIG. 9.

FIG. 11 is a plan view showing forming of a black mark on the substrate prior to step S100 of FIG. 5.

FIG. 12 is a plan view showing the substrate and the separator at step S100 of FIG. 5 according to a fourth embodiment of the method.

FIG. 13 is a cross-sectional view taken along line C-C′ of FIG. 12.

FIG. 14 is a front view showing spraying of a separator ink onto the substrate at step S100 of FIG. 5.

FIG. 15 is a front view showing forming of a separator by curing the separator ink on the substrate with ultraviolet rays at step S100 of FIG. 5.

FIG. 16 is a front view showing spraying of a separator ink onto the substrate at step S100 of FIG. 5.

FIG. 17 is a front view showing forming of a separator by curing the separator ink on the substrate with ultraviolet rays at step S100 of FIG. 5.

FIG. 18 is a front view showing loading of a substrate onto a plate in step S200 of FIG. 5.

FIG. 19 is a front view showing depositing of a deposition material on the substrate at step S300 of FIG. 5.

FIG. 20 is a front view showing separating the substrate from the plate at step S400 of FIG. 5.

FIG. 21 is a front view showing cleaning of the substrate to remove the separator at step S500 of FIG. 5.

FIG. 22 is a plan view showing measurement points for measuring the flatness of a substrate.

FIG. 23 is a block diagram of an electronic device according to an embodiment of the present disclosure.

FIG. 24 is schematic views of various electronic devices according to a variety of embodiments of the present disclosure.

### DETAILED DESCRIPTION

The advantages and features of the present disclosure, and the methods for achieving them, will become clear with reference to the embodiments described in detail below with the accompanying drawings. However, the present disclosure is not limited to the embodiments disclosed below, but may be implemented in various different forms. The example embodiments are provided for illustrative purposes and for fully conveying the scope of the present disclosure to those skilled in the art.

When elements or layers are referred to as “on” another element or layer, this includes examples where an element or layer is directly on the other element or layer, and examples where intervening layers may also be present. Like reference numerals refer to like components throughout the specification of the present disclosure. The shapes, sizes, ratios, angles, numbers, etc. disclosed in the drawings for explaining the embodiments are exemplary, and therefore it should be appreciated that the present disclosure is not limited by specific depictions of any feature in one or more of the drawings of the present disclosure.

Each feature of the various embodiments of the present disclosure may be partially or entirely combined or combined with each other, and may be technically capable of various interconnections and operations. Further, each embodiment may be implemented independently of each other or may be implemented together utilizing features combined from two or more embodiments in a related relationship.

Hereinafter, illustrative examples of the present disclosure will be described in detail with reference to the accompanying drawings.

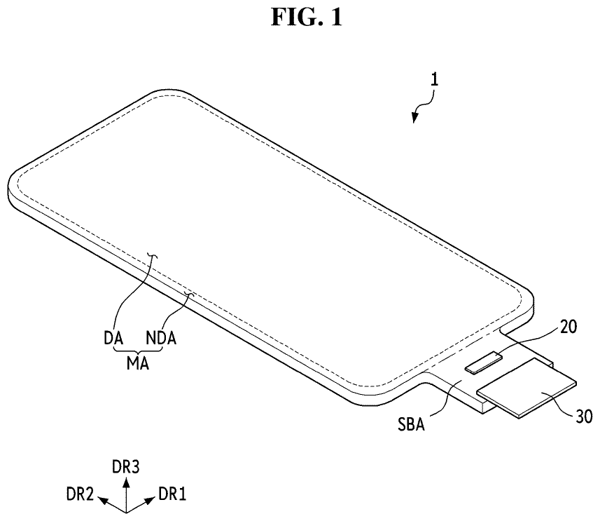

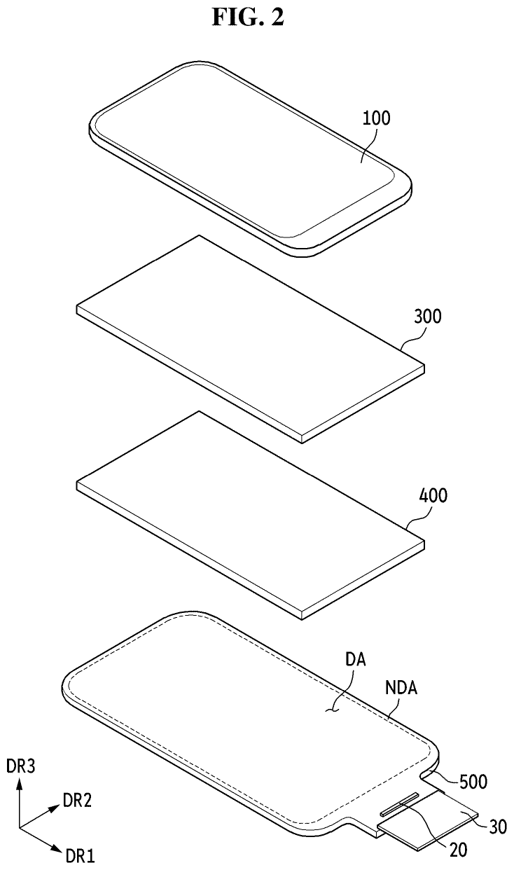

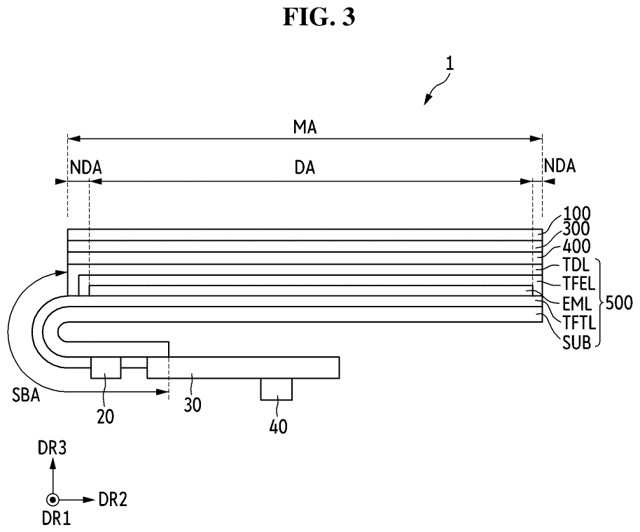

FIG. 1 is a perspective view of a display device according to an embodiment of the present disclosure. FIG. 2 is an exploded, perspective view of a display device according to an embodiment of the present disclosure. FIG. 3 is a side view of a display device according to an embodiment of the present disclosure.

Referring to FIGS. 1 to 3, the display device 1 may include a window member 100, a separator 200, such as an adhesive member, an anti-fingerprint film 300, an anti-reflection film 400 and a display panel 500.

A display device 1 may be configured for displaying moving images or still images. The display device 1 may be used as the display screen of portable electronic devices such as a mobile phone, a smart phone, a tablet personal computer (PC), a smart watch, a watch phone, a mobile communications terminal, an electronic notebook, an electronic book, a portable multimedia player (PMP), a navigation device and a ultra mobile PC (UMPC), as well as the display screen of various products such as a television, a notebook, a monitor, a billboard and the Internet of Things.

According to at least some embodiments of the present disclosure, the display device 1 may be a light-emitting display device such as an organic light-emitting display device using organic light-emitting diodes, a quantum-dot light-emitting display device including quantum-dot light-emitting layer, an inorganic light-emitting display device including an inorganic semiconductor, and a micro-LED display device using micro or nano light-emitting diodes (micro LEDs or nano LEDs). In the following description, an organic light-emitting display device is described as an example of the display device 1 according to one example implementation of an embodiment. It is, however, to be understood that embodiments of the present disclosure are not limited thereto.

In some examples, and as shown in FIGS. 2 and 3, the display device 1 includes a display panel 500, a display driver circuit 20 and a circuit board 30.

The display panel 500 may be formed in a rectangular plane having shorter sides in the first direction DR1 and longer sides in the second direction DR2 intersecting the first direction DR1. In addition, the display panel 500 may have a thickness in the third direction DR3 that intersects the first direction DR1 and the second direction DR2. Each of the corners where the shorter side in the first direction DR1 meets the longer side in the second direction DR2 may be rounded with a predetermined curvature or may be a right angle. The shape of the display panel 500 when viewed from the top is not limited to a quadrangular shape, but may be formed in a different polygonal shape, a circular shape, or an elliptical shape. The display panel 500 may be formed flat, but the present disclosure is not limited thereto. For example, the display panel 500 may be formed at left and right ends, and may include a curved portion having a constant curvature or a varying curvature. In addition, the display panel 500 may be flexible so that it can be curved, bent, folded or rolled.

As shown in FIG. 1, the display panel 500 may include the main area MA and a subsidiary area SBA. Further, and as shown in FIGS. 1-3, the main area MA may include a display area DA where images are displayed, and a non-display area NDA around the display area DA. The display area DA may occupy most of the main area MA. The display area DA may be disposed at the center of the main area MA. The non-display area NDA may be disposed adjacent to the display area DA. The non-display area NDA may be located on the outer side of the display area DA. The non-display area NDA may surround the display area DA. The non-display area NDA may define the border of the display panel 500.

The subsidiary area SBA may be extended from one side of the main area MA in the first direction DR1, as shown in FIG. 1, for example. The length of the subsidiary area SBA in the first direction DR1 may be shorter than the length of the main area MA in the first direction DR1. The length of the subsidiary area SBA in the second direction DR2 may be less than the length of the main area MA in the second direction DR2 or may be substantially equal to it. The subsidiary area SBA may be bent and may be located under the display panel 500, as shown in FIG. 3, for example. In this instance, the subsidiary area SBA may overlap with the main area MA in the third direction DR3.

The display driver circuit 20 may generate signals and voltages for driving the display panel 500. The display driver circuit 20 may be implemented as an integrated circuit (IC) and may be attached to the subsidiary area SBA of the display panel 500 by a chip on glass (COG) technique, a chip on plastic (COP) technique, or an ultrasonic bonding. Alternatively, the display driver circuit 20 may be attached on the circuit board 30 by the chip-on-film (COF) technique.

The circuit board 30 may be attached to one end of the subsidiary area SBA of the display panel 500. Accordingly, the circuit board 30 may be electrically connected to the display panel 500 and the display driver circuit 20. The display panel 500 and the display driver circuit 20 may receive digital video data, timing signals, and driving voltages through the circuit board 30. The circuit board 30 may be, for example, a flexible printed circuit board, a printed circuit board, or a flexible film such as a chip on film.

The touch driver circuit 40 may be disposed on the circuit board 30. The touch driver circuit 40 may be implemented as an integrated circuit (IC) and may be attached on the circuit board 30.

The touch driver circuit 40 may be electrically connected to a plurality of driving electrodes and a plurality of sensing electrodes of the touch detecting layer TDL. The touch driver circuit 40 may apply a touch driving signal to a plurality of driving electrodes, and may sense a touch detection signal, for example, a change in mutual capacitance, of each of a plurality of touch nodes a plurality of sensing electrodes. The touch driver circuit 40 may determine whether there is a user's touch or near proximity, based on the touch sensing signal of each of the plurality of touch nodes. A user's touch refers to circumstances where an object such as the user's finger or a pen is brought into contact with the front surface of the display device 1 disposed on the touch detecting layer TDL. A user's near proximity refers to circumstances when an object such as the user's finger and a pen is hovering over the front of the display device 1.

As shown in FIG. 3, for example, the anti-fingerprint film 300 may be formed on the window member 100. The window member 100 is made of a transparent material, and may be, for example, glass or plastic. For example, the window member 100 may be an ultra thin glass (UTG) having a thickness of 0.1 mm or less or a transparent polyimide film. The anti-fingerprint film 300 may be located on the back surface of the window member 100. The anti-fingerprint film 300 can prevent a user's fingerprint from being left on the display device 1.

The anti-reflection film 400 may be formed on the window member 100. The anti-fingerprint film 300 and/or an anti-reflection film 400 may be deposited on the window member 100 using deposition equipment.

By depositing the anti-fingerprint film 300 and/or the anti-reflection film 400 on the window member 100 using deposition equipment rather than by attaching them with an adhesive, the adhesive strength between the window member 100 and the anti-fingerprint film 300 and/or the anti-reflection film 400 can be further improved.

The anti-reflective film 400 may be located on the back surface of the window member 100. The anti-reflection film 400 may include a plurality of refractive layers having different refractive indices. The anti-reflection film 400 can reduce reflected light through the plurality of refractive layers. The anti-reflection film 400 may be arranged in multiple layers including alternating high-refractive layers and low-refractive layers, and may be arranged so that it has distributed Bragg reflector (DBR) characteristics.

The refractive index of the one or more low-refractive layers may range from 1.20 to 1.60, but the present disclosure is not limited thereto. The low-refractive layer may include, but is not limited to, at least one of silicon resin, silica, silicon oxide (SiOx), and silicon dioxide (SiO₂). The low-refractive layer is not limited to the above-listed materials and may include any material as long as such material can exhibit a low refractive index.

The refractive index of the one or more high-refractive layers may range from 1.70 to 2.80, but the present disclosure is not limited thereto. The high-refractive layer may include at least one of: silicon nitride (Si₃N₄), aluminum nitride (AlN), zirconium nitride (ZrN), chromium nitride (CrN), titanium nitride (TiN), manganese nitride (Mn4N), iron nitride (FeNx), cobalt nitride (CoNx), nickel nitride (Ni₃N), copper nitride (Cu₃N), zinc nitride (Zn2N3), vanadium nitride (VN), molybdenum nitride (Mo₂N), hafnium nitride (HfN), germanium nitride (Ge₃N₄), lead nitride (Pb(N₃)₂), titanium niobate (Ti₄Nb₃O₃₅), titanium dioxide (TiO₂), zirconium dioxide (ZrO₂), lithium niobate (LiNbO₃), lithium tantalate (LiTaO₃), and Lanthanum Titanium (LaTiO₂). The high-refractive layer is not limited to the above-listed materials and may include any material as long as such material can exhibit a high refractive index.

The thickness of the one or more low-refractive layers may be equal to or different from the thickness of the one or more high-refractive layers. The thickness of the one or more low-refractive layers and the thickness of the one or more high-refractive layer may be determined by considering the characteristics of the anti-reflection film 400, such as the target reflection wavelength, hardness, durability, and reflectance.

A light-blocking layer (not shown) for absorbing light incident from the outside, a buffer layer (not shown) for absorbing impact from the outside, and a heat-dissipation layer (not shown) for efficiently discharging heat from the display panel 500 may be further included under the display panel 500.

The light-blocking layer can block transmission of light, thereby preventing elements disposed under the light-blocking layer from being seen from above the display panel 500. The light-blocking layer may include a light-absorbing material such as a black pigment and/or a black dye.

The buffer layer can absorb external shock to prevent the display panel 500 from being damaged. The buffer layer may be made up of a single layer or multiple layers. For example, the buffer layer may be formed of a polymer resin such as polyurethane, polycarbonate, polypropylene and polyethylene, or may be formed of a material having elasticity such as a rubber and a sponge obtained by foaming a urethane-based material or an acrylic-based material.

The heat sink layer may include a first heat dissipation layer including graphite or carbon nanotubes, and a second heat dissipation layer formed of a thin metal film such as copper, nickel, ferrite and silver, which can block electromagnetic waves and have high thermal conductivity.

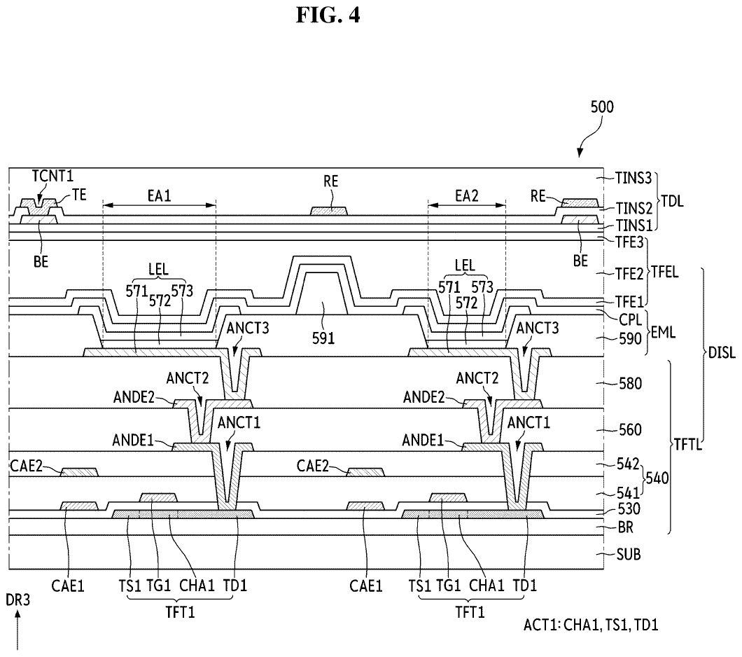

FIG. 4 is a cross-sectional view of a display panel according to an embodiment of the present disclosure. Referring to FIG. 4, the display panel 500 may include a substrate SUB, a display layer DISL disposed on the substrate SUB, and a touch detecting layer TDL disposed on the display layer DISL. The display layer DISL may include a thin-film transistor layer TFTL, an emission material layer EML, and an encapsulation layer TFEL.

The thin-film transistor layer TFTL may be disposed on the substrate SUB. The thin-film transistor layer TFTL may include a barrier layer BR, a thin-film transistor TFT1, a first capacitor electrode CAE1, a second capacitor electrode CAE2, a first anode connection electrode ANDE1, a second anode connection electrode ANDE2, a gate insulator 530, a first interlayer dielectric film 541, a second interlayer dielectric film 542, a first planarization film 560, a second planarization film 580.

The substrate SUB may be made of an insulating material such as a polymer resin. For example, the substrate SUB may be made of polyimide. The substrate SUB may be a flexible substrate that can be bent, folded, or rolled.

The barrier film BR may be disposed on the substrate SUB. The barrier film BR is a film for protecting the thin-film transistors of the thin-film transistor layer TFTL and an emissive layer 572 of the emission material layer EML. The barrier film BR may be made up of multiple inorganic films stacked on one another alternately. For example, the barrier film BR may be made up of multiple layers in which one or more inorganic layers from among a silicon nitride layer, a silicon oxynitride layer, a silicon oxide layer, a titanium oxide layer and an aluminum oxide layer are alternately stacked on one another.

The thin-film transistor layer TFTL may be disposed on the substrate SUB. The thin-film transistor layer TFTL may be disposed in the main area MA and the subsidiary area SBA. The thin-film transistor layer TFTL includes thin-film transistors.

The thin-film transistors TFT1 may be disposed on the barrier film BR. An active layer ACT1 of the thin-film transistor TFT1 may be disposed on the barrier layer BR. The active layer ACT1 of the thin-film transistor TFT1 may include polycrystalline silicon, monocrystalline silicon, low-temperature polycrystalline silicon, amorphous silicon, or an oxide semiconductor.

The active layer ACT1 may include a channel region CHA1, a source region TS1 and a drain region TD1. The channel region CHA1 may overlap with a gate electrode TG1 in the third direction DR3, i.e., the thickness direction of the substrate SUB. The source region TS1 may be disposed on one side of the channel region CHA1, and the drain region TD1 may be disposed on the opposite side of the channel region CHA1. The source region TS1 and the drain region TD1 may not overlap with the gate electrode TG1 in the third direction DR3. The source region TS1 and the drain region TD1 may be formed by doping a silicon semiconductor or an oxide semiconductor with ions or impurities to have conductivity.

The gate insulator 530 may be disposed on the active layer ACT1 of the thin-film transistor TFT1. The gate insulator 530 may be formed of an inorganic layer, for example, a silicon nitride layer, a silicon oxynitride layer, a silicon oxide layer, a titanium oxide layer, or an aluminum oxide layer.

The gate electrode TG1 of the thin-film transistor TFT1 and the first capacitor electrode CAE1 may be disposed on the gate insulator 530. The gate electrode TG1 may overlap with the channel region CHA1 in the third direction DR3. Although the gate electrode TG1 and the first capacitor electrode CAE1 are spaced apart from each other in the example shown in FIG. 4, the gate electrode TG1 and the first capacitor electrode CAE1 may be connected with each other as a single piece. The gate electrode TG1 and the first capacitor electrode CAE1 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

The first interlayer dielectric film 541 may be disposed on the gate electrode TG1 of the thin-film transistor TFT1 and the first capacitor electrode CAE1. The first interlayer dielectric film 541 may be formed of an inorganic layer, for example, a silicon nitride layer, a silicon oxynitride layer, a silicon oxide layer, a titanium oxide layer, or an aluminum oxide layer. The first interlayer dielectric film 541 may be made of a plurality of inorganic films.

The second capacitor electrode CAE2 may be disposed on the first interlayer dielectric layer 541. The second capacitor electrode CAE2 may overlap the first capacitor electrode CAE1 of the thin-film transistor TFT1 in the third direction DR3. In addition, when the gate electrode TG1 and the first capacitor electrode CAE1 are formed as a single piece, the second capacitor electrode CAE2 may overlap the gate electrode TG1 in the third direction DR3. Since the first interlayer dielectric layer 541 has a predetermined dielectric constant, a capacitor can be formed by the first capacitor electrode CAE1, the second capacitor electrode CAE2 and the first interlayer dielectric layer 541 disposed therebetween. The second capacitor electrode CAE2 may be made up of a single layer or multiple layers of molybdenum (Mo), aluminum (Al), chromium (Cr), gold (Au), titanium (Ti), nickel (Ni), neodymium (Nd) and copper (Cu) or an alloy thereof.

A second interlayer dielectric layer 542 may be disposed over the second capacitor electrode CAE2. The second interlayer dielectric film 542 may be formed of an inorganic layer, for example, a silicon nitride layer, a silicon oxynitride layer, a silicon oxide layer, a titanium oxide layer, or an aluminum oxide layer. The second interlayer dielectric film 542 may be made of a plurality of inorganic films.

A first anode connection electrode ANDE1 may be disposed on the second interlayer dielectric film 542. The first anode connection electrode ANDE1 may be connected to the drain electrode DT1 of the thin-film transistor TFT1 through a first connection contact hole ANCT1 that penetrates the gate insulator 530, the first interlayer dielectric film 541 and the second interlayer dielectric film 542. The first anode connection electrode ANDE1 may be made up of a single layer or multiple layers of molybdenum (Mo), aluminum (Al), chromium (Cr), gold (Au), titanium (Ti), nickel (Ni), neodymium (Nd) and copper (Cu) or an alloy thereof.

A first planarization film 560 may be disposed over the first anode connection electrode ANDE1 for providing a flat surface over level differences due to the thin-film transistor TFT1. The first planarization film 560 may be formed of an organic layer such as an acryl resin, an epoxy resin, a phenolic resin, a polyamide resin and/or a polyimide resin.

A second anode connection electrode ANDE2 may be disposed on the first planarization layer 560. The second anode connection electrode ANDE2 may be connected to the first anode connection electrode ANDE1 through a second connection contact hole ANCT2 penetrating the first planarization layer 560. The second anode connection electrode ANDE2 may be made up of a single layer or multiple layers of one of molybdenum (Mo), aluminum (Al), chromium (Cr), gold (Au), titanium (Ti), nickel (Ni), neodymium (Nd) and copper (Cu) or an alloy thereof.

A second planarization film 580 may be disposed on the second anode connection electrode ANDE2. The second planarization film 180 may be formed as an organic layer such as an acryl resin, an epoxy resin, a phenolic resin, a polyamide resin and/or a polyimide resin.

The emission material layer EML may be disposed on the thin-film transistor layer TFTL. The emission material layer EML may be disposed in the display area DA of the main area MA. The emission material layer EML includes light-emitting elements disposed in emission areas.

An emission material layer EML including light-emitting elements LEL and a bank 590 may be disposed on the second planarization film 580. Each of the light-emitting elements LEL includes a pixel electrode 571, an emissive layer 572, and a common electrode 573.

The pixel electrode 571 may be disposed on the second planarization film 580. The pixel electrode 571 may be connected to the second anode connection electrode ANDE2 through a third connection contact hole ANCT3 that penetrates the second planarization film 580.

In the top-emission structure in which light exits from the emissive layer 572 toward the common electrode 573, the pixel electrode 571 may be made of a metal material having a high reflectivity such as a stack structure of aluminum and titanium (Ti/Al/Ti), a stack structure of aluminum (Al) and Indium Tin Oxide (ITO) (ITO/Al/ITO), an APC alloy or a stack structure of an APC alloy and ITO (ITO/APC/ITO). The APC alloy is an alloy of silver (Ag), palladium (Pd) and copper (Cu).

The bank 590 may partition the pixel electrode 571 on the second planarization film 580 to define the emission areas EA1 and EA2. The bank 590 may be disposed to cover the edges of the pixel electrode 571. The bank 590 may be formed of an organic film such as an acryl resin, an epoxy resin, a phenolic resin, a polyamide resin and/or a polyimide resin.

In each of the first emission area EA1 and the second emission area EA2, the pixel electrode 571, the emissive layer 572 and the common electrode 573 are stacked on one another sequentially, so that holes from the pixel electrode 571 and electrons from the common electrode 573 are recombined with each other in the emissive layer 572 to emit light.

The emissive layer 572 may be disposed on the pixel electrode 571 and the bank 590. The emissive layer 572 may include an organic material to emit light of a certain color. For example, the emissive layer 572 may include a hole transporting layer, an organic material layer, and an electron transporting layer.

The common electrode 573 may be disposed on the emissive layer 572. The common electrode 573 may be disposed to cover the emissive layer 572. The common electrode 573 may be a common layer formed commonly across the first emission area EA1 and the second emission area EA2.

In the top-emission organic light-emitting diode, the common electrode 573 may be formed of a transparent conductive material (TCP) such as ITO and IZO that can transmit light, or a semi-transmissive conductive material such as magnesium (Mg), silver (Ag) and an alloy of magnesium (Mg) and silver (Ag). When the common electrode 173 is formed of a semi-transmissive metal material, the light extraction efficiency can be increased by using microcavities.

A spacer 591 may be disposed on the bank 590. The spacer 591 may support a mask during a process of fabricating the emission layer 572. The spacer 591 may be formed of an organic layer such as an acryl resin, an epoxy resin, a phenolic resin, a polyamide resin and/or a polyimide resin.

According to some embodiments of the present disclosure, the display panel 500 may further include a capping layer CPL disposed on the common electrode 573. The capping layer CPL may be made of an inorganic material. For example, the capping layer CPL may include at least one of: silicon nitride, aluminum nitride, zirconium nitride, titanium nitride, hafnium nitride, tantalum nitride, silicon oxide, aluminum oxide, titanium oxide, tin oxide, cerium oxide and silicon oxynitride.

The encapsulation layer TFEL may be disposed on the emission material layer EML. The encapsulation layer TFEL may be disposed in the display area DA and the non-display area NDA of the main area MA. The encapsulation layer TFEL includes at least one inorganic film and at least one organic film for encapsulating the emission material layer.

An encapsulation layer TFEL may be disposed on the common electrode 573. The encapsulation layer TFEL may include at least one inorganic layer to prevent permeation of oxygen or moisture into the emission material layer EML. In addition, the encapsulation layer TFEL may include at least one organic film to protect the emission material layer EML from particles such as dust. For example, the encapsulation layer TFEL may include a first inorganic encapsulation layer TFE1, an organic encapsulation layer TFE2 and a second inorganic encapsulation layer TFE3.

The first inorganic encapsulation film TFE1 may be disposed on the common electrode 573, the organic encapsulation film TFE2 may be disposed on the first inorganic encapsulation film TFE1, and the second inorganic encapsulation film TFE3 may be disposed on the organic encapsulation film TFE2. The first inorganic encapsulation film TFE1 and the second inorganic encapsulation film TFE3 may each be made up of multiple layers in which one or more inorganic layers from among a silicon nitride layer, a silicon oxynitride layer, a silicon oxide layer, a titanium oxide layer and an aluminum oxide layer are alternately stacked on one another. The organic encapsulation film TFE2 may be an organic film such as an acryl resin, an epoxy resin, a phenolic resin, a polyamide resin, a polyimide resin, etc.

A touch detecting layer TDL may be disposed on the encapsulation layer TFEL. The touch detecting layer TDL includes a first touch insulating film TINS1, connection electrodes BE, a second touch insulating film TINS2, the driving electrodes TE, the sensing electrodes RE, and a third touch insulating film TINS3. The touch detecting layer TDL may sense a touch of a person or an object using sensor electrodes.

The first touch insulating film TINS1 may be disposed on the encapsulation layer TFEL. The first touch insulating film TINS1 may be formed of an inorganic film, for example, a silicon nitride layer, a silicon oxynitride layer, a silicon oxide layer, a titanium oxide layer, or an aluminum oxide layer.

The connection electrode BE may be disposed on the first touch insulating film TINS1. The connection electrode BE may be made up of a single layer or multiple layers of molybdenum (Mo), aluminum (Al), chromium (Cr), gold (Au), titanium (Ti), nickel (Ni), neodymium (Nd) and copper (Cu) or an alloy thereof.

The second touch insulating film TINS2 may be disposed over the connection electrodes BE. The second touch insulating layer TINS2 may be formed of an inorganic layer, for example, a silicon nitride layer, a silicon oxynitride layer, a silicon oxide layer, a titanium oxide layer, or an aluminum oxide layer. Alternatively, the second touch insulating layer TINS2 may be formed of an organic layer such as an acryl resin, an epoxy resin, a phenolic resin, a polyamide resin and/or a polyimide resin.

The driving electrodes TE and the sensing electrodes RE may be disposed on the second touch insulating film TINS2. The driving electrodes TE and the sensing electrodes RE may be made up of a single layer or multiple layers of molybdenum (Mo), aluminum (Al), chromium (Cr), gold (Au), titanium (Ti), nickel (Ni), neodymium (Nd) and copper (Cu) or an alloy thereof.

The driving electrodes TE and the sensing electrodes RE may overlap with the connection electrodes BE in the third direction DR3. The driving electrodes TE may be connected to the connection electrodes BE through touch contact holes TCNT1 penetrating through the first touch insulating film TINS1.

The third touch insulating film TINS3 may be formed on the driving electrodes TE and the sensing electrodes RE. The third touch insulating layer TINS3 may provide a flat surface over the driving electrodes TE, the sensing electrodes RE and the connection electrodes BE which having different heights. The third touch insulating film TINS3 may be formed of an organic layer such as an acryl resin, an epoxy resin, a phenolic resin, a polyamide resin and/or a polyimide resin.

Hereinafter, a method for fabricating the display device according to a variety of embodiments of the present disclosure will be described with reference to the accompanying drawings.

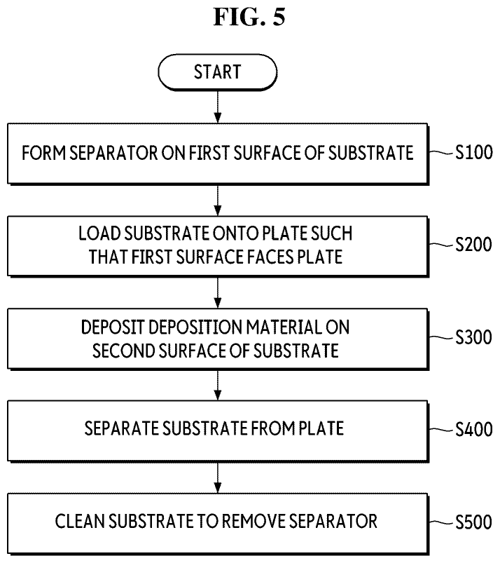

FIG. 5 is a flowchart illustrating a method of fabricating a display device according to an embodiment of the present disclosure. Steps and other details associated with the method, including the devices produced through such method, will now be described.

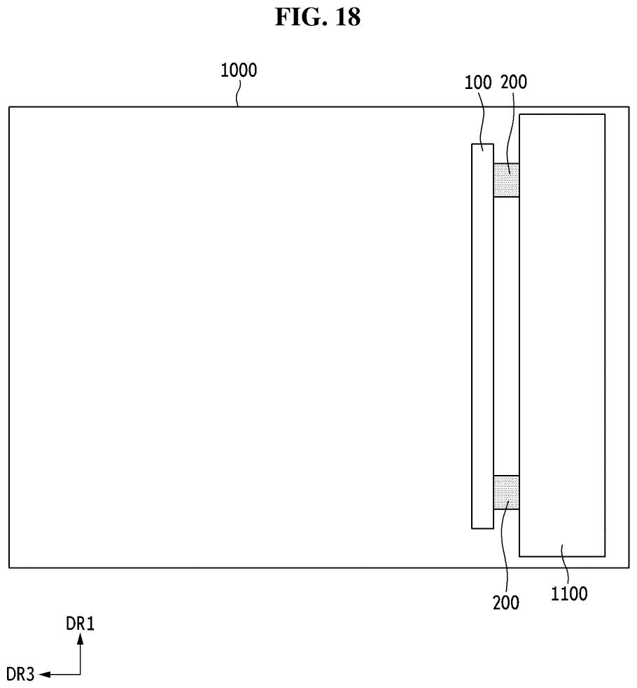

Initially, a separator 200 may be formed on a surface of a substrate 100 (step S100). The separator 200 may have a thickness that is 20% or more of the thickness of the substrate 100. In some examples, the thickness of the separator 200 may be 30% or more of the thickness of the substrate 100. In examples where the thickness of the substrate 100 is equal to or greater than 500 μm, the thickness of the separator 200 may be equal to or greater than 100 μm. In some examples, the thickness of the separator 200 may be equal to or greater than 150 μm. The thickness of the separator 200 must be sufficiently large so that the substrate 100 and a plate 1100 (e.g., see FIG. 18) can be sufficiently spaced apart from each other. Further details respecting how plate 1100 relates to substrate 100 are described below.

Turning to a surface area (i.e., in plane that is coincident with directions DR1 and DR2) of the separator 200, the surface area of the separator 200 may be equal to or less than 50% of the surface area of the substrate 100. In some examples, the surface area of the separator 200 may be equal to or less than 30% of the surface area of the substrate 100. The smaller the area of separator 200 is, the less heat may be transferred by the plate 1100.

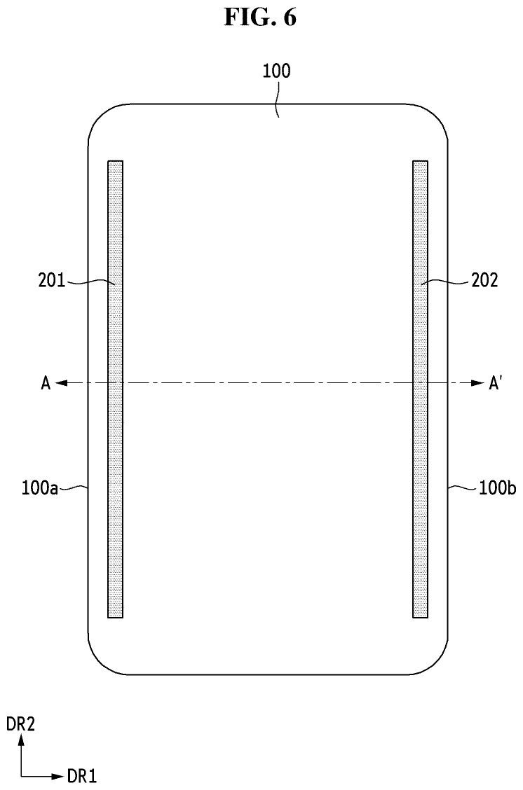

FIG. 6 is a plan view showing the substrate and the separator at step S100 of FIG. 5 according to a first embodiment.

According to the first embodiment where the separator 200 is formed on the substrate 100, the forming of the separator 200 may include forming a first separator 201 on a first surface of the substrate 100 and subsequently forming a second separator 202 on the first surface of the substrate 100 that is spaced apart from the first separator 201. Alternatively, the forming of the separator 200 may include simultaneously forming a first separator 201 and a second separator 202 spaced apart from the first separator 201 on the first surface of the substrate 100.

Referring to FIG. 6, the first separator 201 may be adjacent to a first side 100a of the substrate 100 and may extend in the second direction DR2 along the edge of the first side 100a of the substrate 100. The second separator 202 may be adjacent to a second side 100b of the substrate 100, the second side 100b being opposite the first side 100a of the substrate 100, and may extend in the second direction DR2 along the edge of the second side 100b of the substrate 100. In some examples, the first separator 201 may be parallel to the second separator 202.

Although the first separator 201 and the second separator 202 are spaced apart from respective edges of the substrate 100 in FIG. 6, the present disclosure is not limited thereto. In some examples, the first separator 201 and the second separator 202 may be directly adjacent to the respective edges of the substrate 100.

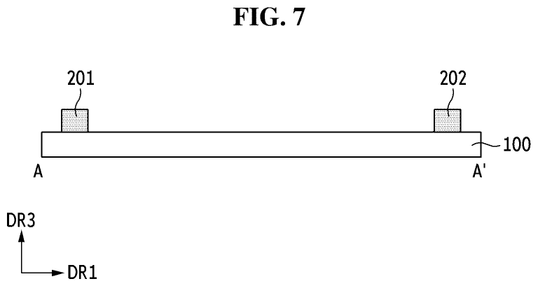

FIG. 7 is a cross-sectional view taken along line A-A′ of FIG. 6. As shown in FIG. 7, the thickness of the first separator 201 may be equal to the thickness of the second separator 202. Since the first separator 201 and the second separator 202 are spaced apart from each other in the first embodiment shown in FIGS. 6-7, convection may occur between the first separator 201 and the second separator 202.

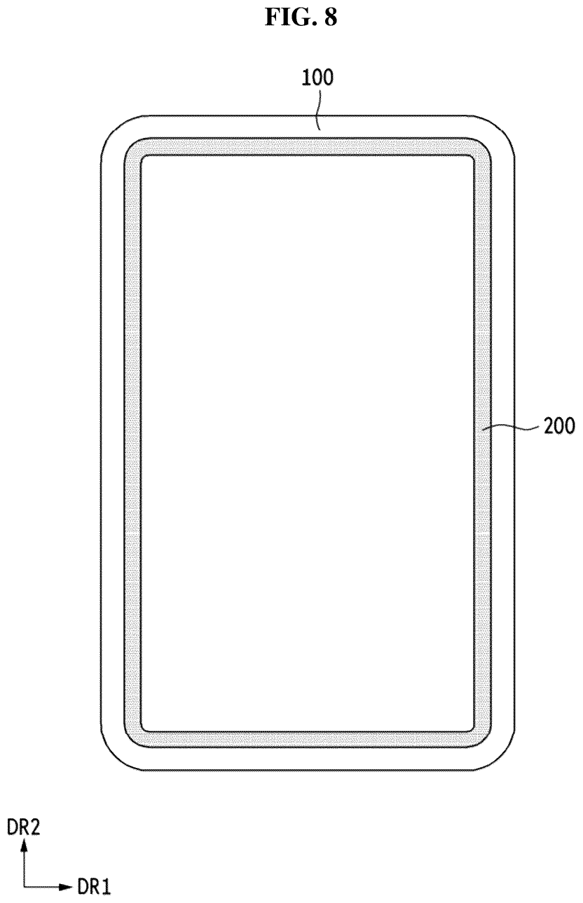

FIG. 8 is a plan view showing the substrate and the separator at step S100 of FIG. 5 according to a second embodiment.

Referring to FIG. 8, a separator 200 may be formed along edges on the first surface of the substrate 100. Although the separator 200 is spaced apart from the edges of the substrate 100 in FIG. 8, the present disclosure is not limited thereto. In some examples, the separator 200 may be directly adjacent to the edges of the substrate 100.

As shown in FIG. 8, when the separator 200 is formed on the first surface of the substrate 100 along the edges of the first surface of the substrate 100, the characteristics of the substrate 100 and the separator 200 when viewed in cross-section may be similar to that of FIG. 7.

When loading the substrate 100 on which the separator 200 is formed onto a plate 1100, a process described in greater detail below, a distance between the substrate 100 and the plate 1100 may increase due to the thickness of the separator 200. In addition, convection may occur where the substrate 100 is exposed inside the separator 200.

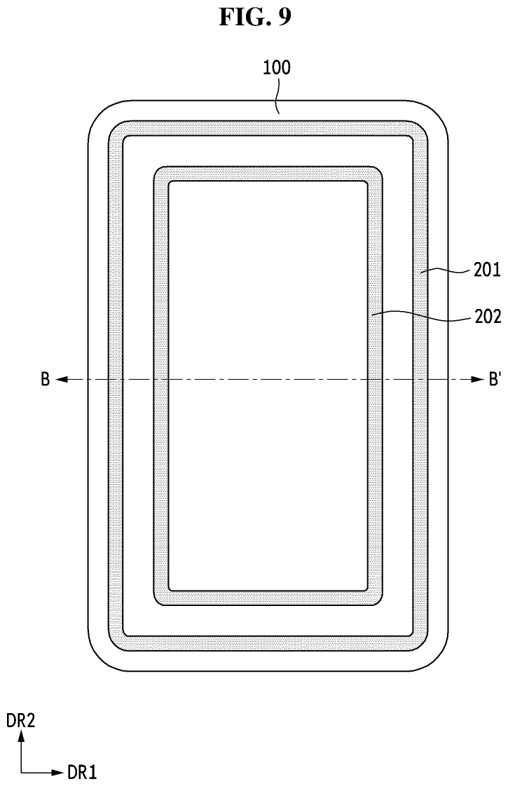

FIG. 9 is a plan view showing the substrate and the separator at step S100 of FIG. 5 according to a third embodiment.

Referring to FIG. 9, a first separator 201 may be formed on the first surface of the substrate 100 along edges of the first surface of the substrate 100, and a second separator 202 may be formed on the first surface on the inner side of the first separator 201. The first separator 201 may be formed along the edges of the first surface of the substrate 100, and the second separator 202 may be formed on the inner side of the first separator 201 such that the second separator 202 is entirely spaced apart from the first separator 201. The distance between the first separator 201 and the second separator 202 may be constant around a periphery of the respective separators. The distance between the edges of the substrate 100 and the first separator 201 may be smaller than the distance between the edges of the substrate 100 and the second separator 202. In some examples, a minimum distance between the first separator 201 and the edge of the substrate 100 may be less than a minimum distance between the second separator 202 and the edge of the substrate 100.

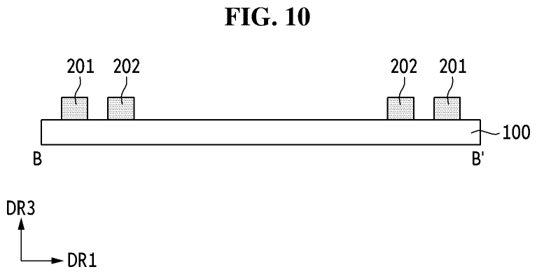

FIG. 10 is a cross-sectional view taken along line B-B′ of FIG. 9. As shown in FIG. 10, the thickness of the first separator 201 may be equal to the thickness of the second separator 202. Since the first separator 201 and the second separator 202 are spaced apart from each other in the third embodiment depicted in FIGS. 9-10, convection may occur between the first separator 201 and the second separator 202.

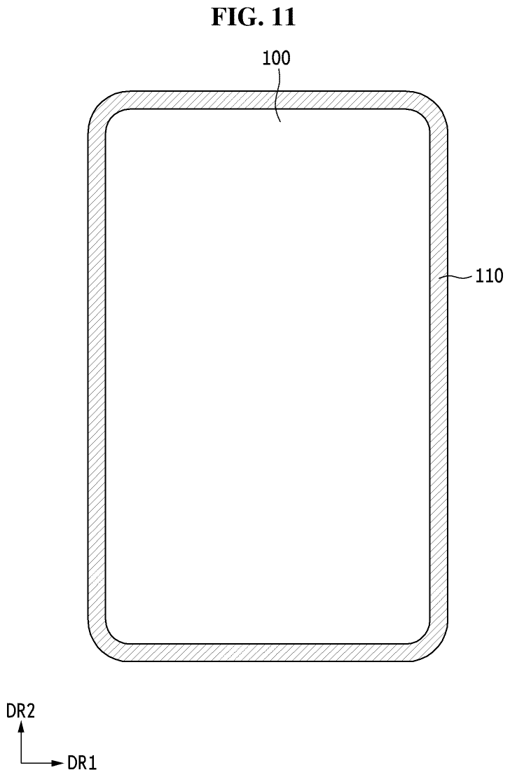

In some examples of the contemplated embodiments, the method may further include forming a black mark 110 on an edge of the first surface of the substrate 100 prior to the forming of the separator 200 on the substrate 100. FIG. 11 is a plan view showing one example of the forming of a black mark on the substrate prior to step S100 of FIG. 5. As shown in FIG. 11, the black mark 110 may be formed along the edges of the substrate 100.

In some examples, the black mark 110 may be formed in the non-display area NDA of the substrate 100. On the black mark 110, a receiver (not shown) may be formed to allow a user to hear the other party's voice during a phone call. The receiver (not shown) may be covered by a receiver grill (not shown) to protect the inside of the receiver (not shown) from the outside.

In some examples, the thickness of the black mark 110 may be equal to or less than 20 μm. Since the thickness of the black mark 110 is small, when the substrate 100 is loaded onto the plate 1100, it is difficult to ensure a sufficient distance between the substrate 100 and the plate 1100 based on the black mark 110 alone. And, because the thickness of the black mark 110 is small, heat may be easily transferred from the plate 1100 to the substrate 100.

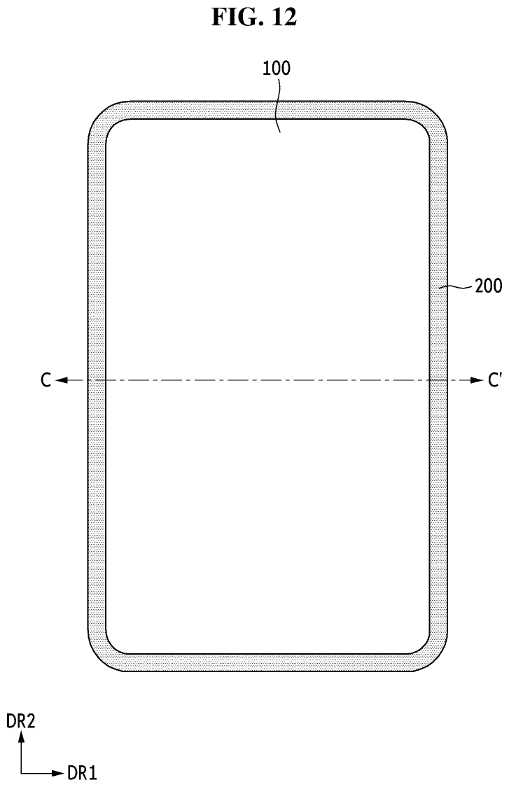

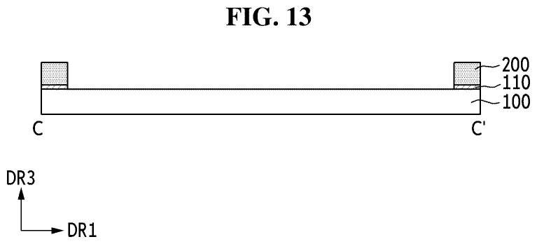

FIG. 12 is a plan view showing the substrate and the separator at step S100 of FIG. 5 according to a fourth embodiment. In FIG. 12, a separator 200 may be formed on the black mark 110. FIG. 13 is a cross-sectional view taken along line C-C′ of FIG. 12.

As shown in FIG. 13, since the separator 200 is formed on the black mark 110, when the substrate 100 on which the separator 200 is formed is loaded onto the plate 1100, the distance between the substrate 100 and the plate 1100 may be equal to the sum of the thickness of the black mark 110 and the thickness of the separator 200.

The separator 200 may be formed into the shapes shown in FIGS. 6 to 13, but the present disclosure is not limited thereto. The shape of the separator 200 is not particularly limited herein as long as the substrate 100 and the plate 1100 can be sufficiently spaced apart from each other when the substrate 100 is placed against the plate 1100. As long as there is a space between the substrate 100 and the plate 1100 that allows convection to occur, the shape of the separator 200 is not particularly limited herein.

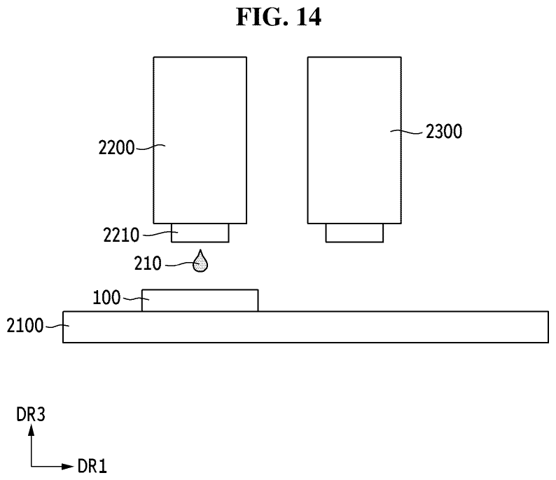

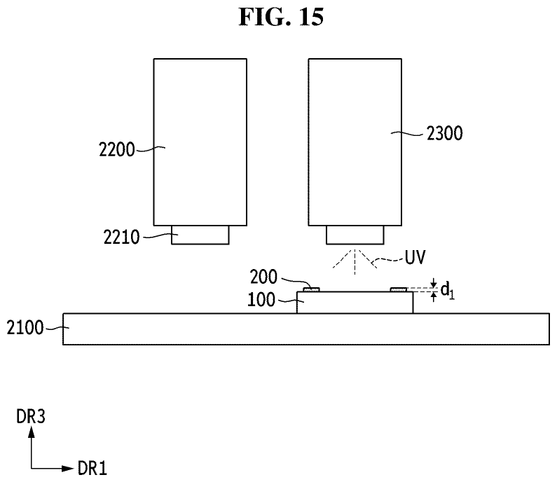

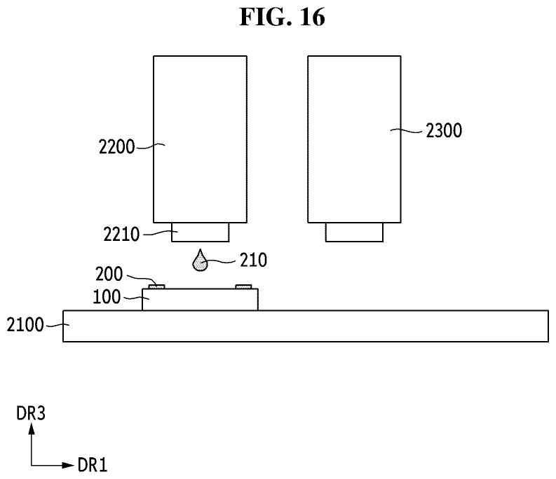

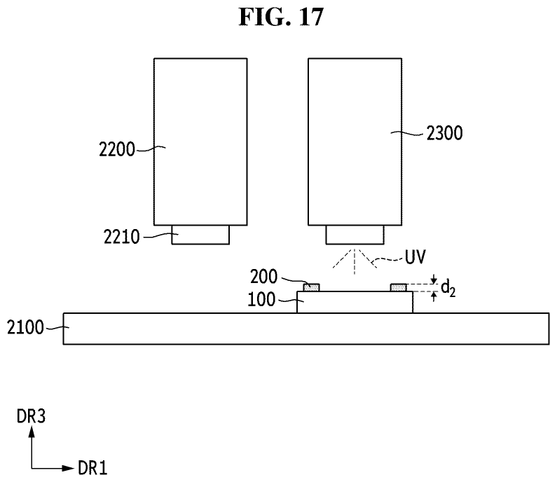

FIG. 14 is a front view showing spraying of a separator ink onto the substrate at step S100 of FIG. 5. FIG. 15 is a front view showing forming of a separator by curing the separator ink on the substrate with ultraviolet rays at step S100 of FIG. 5. FIG. 16 is a front view showing spraying of additional separator ink onto the substrate at step S100 of FIG. 5. FIG. 17 is a front view showing continued forming of a separator by curing the separator ink on the substrate with ultraviolet rays at step S100 of FIG. 5.

Referring to FIGS. 14 to 17, the separator 200 may be formed on the substrate 100. In some examples, the substrate 100 may be positioned on a baseplate 2100. According to an embodiment of the present disclosure, the separator 200 may be formed by spraying the separator ink 210 onto the substrate 100 by using methods such as ink-jet printing and curing the separator ink 210 with ultraviolet light.

The separator ink 210 may be sprayed onto the substrate 100 through a nozzle 2210 of an inkjet printing apparatus 2200. In some examples, and as shown in FIG. 15, the separator ink 210 that is sprayed onto the substrate 100 may be cured or dried by being irradiated with ultraviolet light UV through an ultraviolet lamp 2300.

The process of spraying the separator ink 210 onto the substrate 100 and the process of curing the separator ink 210 with ultraviolet light UV may be performed simultaneously, but the methods contemplated by the present disclosure are not limited thereto. Indeed, the spraying and curing steps may alternatively be performed in sequence, one after the other. For example, after the process of spraying the separator ink 210 onto the substrate 100 has been completed, the process of curing the separator ink 210 with ultraviolet light may be performed.

Referring to FIGS. 14 and 15, when the spraying and curing of the separator ink 210 on the substrate 100 is performed, i.e., completed once, the separator 200, e.g., a removable portion, may be formed on the substrate 100 with a thickness of d1. Referring to FIGS. 16 and 17, the spraying and curing of the separator ink 210 may be performed one more time (i.e., a second time) on the substrate 100 where the separator 200 having the thickness of d1 is already formed. By performing the spraying and curing the separator ink 210 on the substrate 100 twice, the separator 200 having a thickness of d2 may be formed on the substrate 100, where d2 is greater than d1. By performing the spraying and curing the separator ink 210 on the substrate 100 over and over, the separator 200 formed on the substrate 100 may become thicker. In some examples, the thickness of the separator 200 may be equal to or greater than 20% of the thickness of the substrate 100. The spraying and curing of the separator ink 210 on the substrate 100 may be repeated until the thickness of the separator 200 formed on the substrate 100 becomes at least 20% of the thickness of the substrate 100.

In some examples, the separator ink 210 used to form the separator 200 may include a polymer resin having carboxyl functional groups or hydroxyl functional groups. In some examples, the separator ink 210 may include, but is not limited to, at least one of: (meth)acrylic acid, 2-(meth)acryloyloxy acetic acid, 3-(meth)acryloyloxy propyl acid, 4-(meth)acryloyloxy butyric acid, an acrylic acid dimer, itaconic acid and maleic acid. The separator ink 210 of such examples is not particularly limited as long as it has carboxyl groups and can be cured by ultraviolet rays. In some examples, the separator ink 210 may include, but is not limited to, at least one of: 2-hydroxyethyl (meth)acrylate, 3-hydroxypropyl (meth) acrylate, 4-hydroxybutyl (meth)acrylate, and 6-hydroxyhexyl (meth)acrylate. The separator ink 210 of such examples is not particularly limited as long as it has hydroxyl groups and can be cured by ultraviolet rays.

The separator ink 210 may be dissolved in water or an alkaline solution.

With the separator 200 formed on the substrate 100, the method proceeds to step s200 as shown in FIG. 5. In step S200, the substrate 100 may be loaded onto the plate 1100 such that the first surface of the substrate 100 faces the plate 1100. FIG. 18 is a front view showing a substrate being loaded onto a plate at step S200 of FIG. 5.

With continued reference to FIG. 18, the substrate 100 may be loaded onto the plate 1100 in such a way that the surface of the substrate 100 on which the separator 200 is formed faces the plate 1100. In doing so, there may be space between the substrate 100 and the plate 1100 that is equal to the thickness of the separator 200. This arrangement prepares the substrate 100 for further steps using a thin film deposition apparatus 1000.

Unlike the embodiments contemplated by the present disclosure, if the substrate 100 is loaded onto the plate 1100 without the separator 200 on the substrate 100, the substrate 100 and the plate 1100 may come into contact with each other. In particular, when deposition is performed at a high temperature, e.g., at a temperature of 100° C. or higher inside a thin-film deposition apparatus 1000, warping of the substrate 100 may occur. Specifically, heat generated in the plate 1100 may be transferred from the plate 1100 to the substrate 100 through respective surfaces of the plate 1100 and the substrate 100 where the plate 1100 and the substrate 100 come into contact. In addition, convective heat may be transferred to a second surface of the substrate 100, which is the opposite surface of the first surface of the substrate 100 that comes into contact with the plate 1100, due to the convection inside the thin-film deposition apparatus 1000. There may be a difference between the temperature of the conductive heat transferred from the plate 1100 and the temperature of the convective heat inside the thin-film deposition apparatus 1000, resulting in warping of the substrate 100.

According to embodiments of the present disclosure, in order to reduce the difference between the convective heat transferred to the substrate 100 inside a thin-film deposition apparatus 1000 and the conductive heat transferred from the plate 1100, the separator 200 is formed on the substrate 100. With the inclusion of the separator 200, there may be a gap between the substrate 100 and the plate 1100 by the thickness of the separator 200, and convective heat may be generated in the gap instead of conductive heat from the plate 1100. Accordingly, since the first and second surfaces of the substrate 100 inside the thin-film deposition apparatus 1000 are only affected by convective heat, the temperature difference between the first surface and the second surface of the substrate 100 can be reduced. Since the resultant temperature difference between the heat received by the first surface and the second surface of the substrate 100 is trivial, it is possible to prevent warping of the substrate 100, and in this way the flatness of the surfaces of the substrate 100 can be improved.

Once the substrate 100 is loaded onto the plate 1100, the above mentioned thin-film deposition apparatus 1000 may perform at least one of: physical vapor deposition (PVD), chemical vapor deposition (CVD), thermal deposition, sputtering, vacuum thermal deposition, and plasma deposition. Using the thin-film deposition apparatus 1000, a deposition material may be deposited on the second surface of the substrate 100 (step S300).

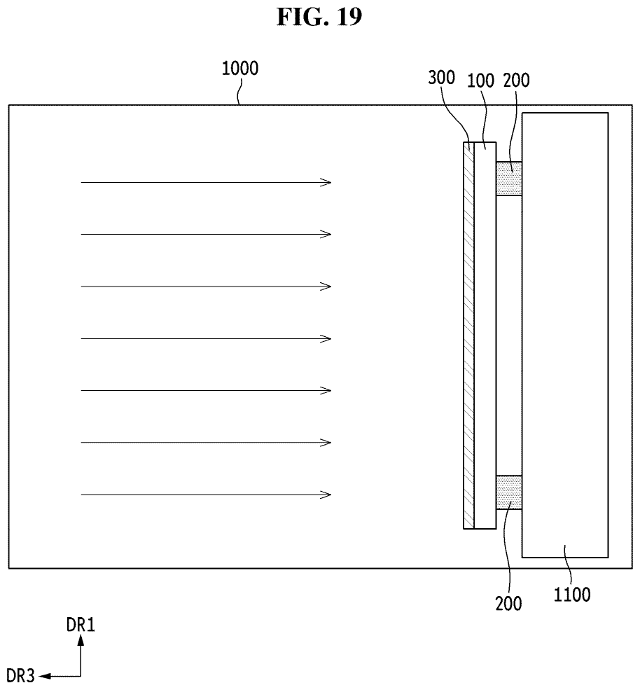

FIG. 19 is a front view showing depositing of a deposition material on the substrate at step S300 of FIG. 5. As shown in FIG. 19, a deposition material 300, 400 may be deposited on the second surface of the substrate 100, which is the opposite side of the first surface of the substrate 100 on which the separator 200 is formed. The deposition material 300, 400 may be, but is not limited to, an anti-fingerprint film 300 or an anti-reflection film 400. When the deposition material 300, 400 is the anti-fingerprint film 300, the above-listed materials may be deposited, but the present disclosure is not limited thereto. When the deposition material 300, 400 is the anti-reflection film 400, the above-listed materials may be deposited, but the present disclosure is not limited thereto.

The deposition may be carried out at a temperature of 100° C. (100 degrees Celsius) or higher. In some examples, the temperature in the thin-film deposition apparatus 1000 may be 150° C. or higher.

In the following descriptions, the substrate 100 is a window member 100 and the deposition material 300, 400 is the anti-fingerprint film 300 or the anti-reflection film 400. It should be understood, however, that the embodiments of the present disclosure are not limited thereto. The embodiments of the present disclosure may utilize any deposition material formed on a substrate by deposition inside the high-temperature thin-film deposition apparatus 1000.

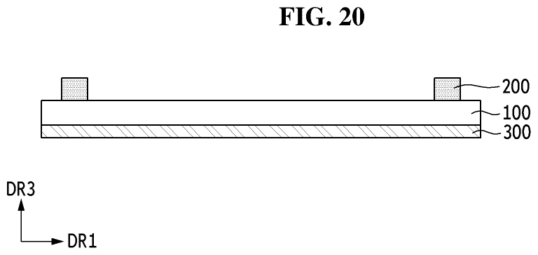

Upon completion of deposition of the deposition material, the substrate 100 may be separated from the plate 1100 (step S400 in FIG. 5). FIG. 20 is a front view showing a separation of the substrate from the plate at step S400 of FIG. 5. As shown in FIG. 20, it can be seen that a separator 200 is arranged on a first surface of the substrate 100, and a deposition material 300, 400 is arranged on the second surface of the substrate 100.

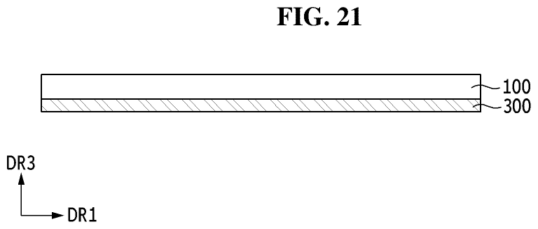

Subsequently, the substrate 100 may be cleaned to remove the separator 200 (step S500). FIG. 21 is a front view showing cleaning the substrate to remove the separator at step S500 of FIG. 5.

The substrate 100 may be cleaned using at least one of water and an alkaline solution. For example, when the separator 200 is formed on the substrate 100 using a polymer resin having hydroxyl functional groups, the substrate 100 on which the separator 200 is formed may be cleaned with water to remove the separator 200. Alternatively, when the separator 200 is formed on the substrate 100 using a polymer resin having carboxylic groups, the substrate 100 on which the separator 200 is formed may be cleaned with an alkaline solution to remove the separator 200.

The process of cleaning the substrate 100 is one that has been performed typically after depositing a deposition material on the substrate 100. It is not an additional process for removing the separator 200 but a process for removing by-products generated during the deposition process.

The separator 200 separates the substrate 100 from the plate 1100 to prevent warping of the substrate 100 due to the conductive heat of the plate 1100. The separator 200 may be easily removed during the cleaning process and may be excluded from the final display device.

Hereinafter, certain embodiments of the present disclosure will be described in greater detail. It should be understood that the following embodiments of the present disclosure are merely illustrative and are not intended to limit the scope of the present disclosure.

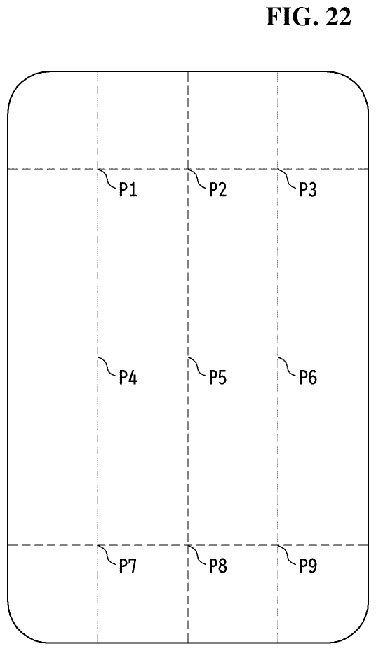

FIG. 22 is a plan view showing measurement points for measuring the flatness of a substrate.

Example window members were produced to evaluate flatness, and the results of such evaluation are summarized in Table 1 below. The flatness of the respective window members used in such examples, encompassing Examples 1 to 20, was measured with the measurement points shown in FIG. 22. The flatness was obtained by measuring the depth of the window member in mm at each measurement point.

TABLE 1

| (mm) | P1 | P2 | P3 | P4 | P5 | P6 | P7 | PB | P9 | MAX − MIN |
|---|---|---|---|---|---|---|---|---|---|---|
| EXAMPLE 1 | 0.002 | −0.0003 | 0.0035 | −0.001 | −0.0068 | −0.0117 | 0.0031 | −0.0008 | −0.0001 | 0.015 |
| EXAMPLE 2 | 0.0011 | 0.0009 | −0.0038 | 0.0018 | 0.0054 | −0.0005 | −0.0036 | −0.0017 | 0.0009 | 0.009 |
| EXAMPLE 3 | −0.0034 | −0.0016 | −0.0011 | 0.0051 | 0.0096 | 0.0013 | −0.0013 | 0.0036 | −0.0038 | 0.013 |
| EXAMPLE 4 | 0.0014 | 0.0015 | 0 | −0.0046 | −0.0077 | −0.0087 | 0.0003 | 0.0093 | 0.006 | 0.018 |
| EXAMPLE 5 | −0.004 | −0.0012 | −0.0024 | 0.0078 | 0.0128 | 0.0046 | −0.0023 | −0.0038 | −0.0042 | 0.017 |
| EXAMPLE 6 | 0.0064 | −0.0059 | −0.0073 | −0.0067 | −0.0018 | −0.0023 | −0.0053 | 0.0054 | 0.0081 | 0.015 |
| EXAMPLE 7 | 0.007 | 0.004 | −0.0017 | −0.0128 | −0.0104 | −0.0099 | −0.0019 | 0.0016 | 0.007 | 0.020 |
| EXAMPLE 8 | 0.0019 | 0.0041 | 0.0071 | −0.0136 | −0.0179 | −0.0181 | 0.0069 | 0.0019 | 0.0019 | 0.025 |
| EXAMPLE 9 | 0.0052 | 0.0045 | −0.0008 | −0.0038 | −0.0094 | −0.0138 | −0.0004 | 0.0059 | 0.0054 | 0.020 |
| EXAMPLE 10 | 0.009 | −0.0033 | −0.004 | −0.0088 | −0.0096 | −0.0071 | −0.004 | −0.001 | 0.0087 | 0.019 |
| EXAMPLE 11 | 0 | 0 | 0.0007 | 0.0021 | −0.0006 | −0.007 | 0.0002 | 0.0011 | −0.0004 | 0.009 |
| EXAMPLE 12 | 0.0015 | 0.0005 | −0.0046 | 0.0045 | 0.0054 | −0.002 | −0.004 | −0.0019 | 0.0018 | 0.010 |
| EXAMPLE 13 | 0.0013 | −0.002 | 0.0027 | −0.0056 | −0.0109 | −0.0112 | 0.0026 | 0.0005 | 0.0043 | 0.016 |
| EXAMPLE 14 | 0.0089 | −0.0057 | −0.0057 | −0.0043 | −0.0066 | −0.0062 | −0.0054 | −0.0005 | 0.0086 | 0.016 |
| EXAMPLE 15 | 0.0002 | −0.0071 | −0.0033 | 0.0077 | 0.0051 | 0.0067 | −0.0028 | −0.0025 | −0.0002 | 0.015 |
| EXAMPLE 16 | 0.0022 | 0.001 | −0.0033 | −0.0009 | 0.0025 | −0.0052 | −0.0033 | −0.0016 | 0.002 | 0.008 |
| EXAMPLE 17 | −0.0007 | 0.0036 | −0.002 | 0.0011 | 0.0021 | −0.002 | −0.0018 | 0.0001 | 0.0024 | 0.006 |
| EXAMPLE 18 | 0.0069 | 0.0068 | 0.0004 | −0.0169 | −0.0148 | −0.0157 | 0.0004 | 0.0048 | 0.0071 | 0.024 |
| EXAMPLE 19 | 0.0002 | 0.002 | −0.0027 | 0.0072 | 0.0049 | 0.002 | −0.0027 | −0.0021 | 0.0002 | 0.010 |
| EXAMPLE 20 | 0.003 | −0.0026 | −0.0034 | 0.0039 | −0.0001 | −0.0016 | −0.0025 | −0.0005 | 0.003 | 0.007 |

In Table 1, Max-Min represents the difference between the largest flatness and smallest flatness among all measurement points that were measured. The average value of Max-Min including Examples 1 to 20 collectively is 0.015 mm.

In Examples 1 to 20, a separated portion was formed with a polymer resin having hydroxyl functional groups on a first surface of a window member, and a substrate was loaded onto a plate such that it faces the surface of the window member. An anti-reflection film was deposited on a second surface of the window member opposite the first surface of the window member at the temperature of 150° C. using the thin-film deposition apparatus. The window member on which the anti-reflection film was formed was separated from the plate and washed with water.

In Comparative Examples 1 to 20, the flatness of the window member was measured with the measurement points shown in FIG. 22. The flatness of the window member used in Comparative Examples 1 to 20 is shown in Table 2 below. The flatness was obtained by measuring the depth of the window member in mm at each measurement point.

TABLE 2

| (mm) | P1 | P2 | P3 | P4 | P5 | P6 | P7 | P8 | P9 | MAX − MIN |
|---|---|---|---|---|---|---|---|---|---|---|
| COMPARATIVE | 0.002 | 0.009 | 0.007 | −0.015 | −0.01 | −0.011 | 0.01 | 0.007 | 0.001 | 0.025 |
| EXAMPLE 1 | | | | | | | | | | |
| COMPARATIVE | 0.002 | 0.005 | 0.006 | −0.008 | −0.009 | −0.009 | 0.007 | 0.003 | 0.004 | 0.016 |
| EXAMPLE 2 | | | | | | | | | | |
| COMPARATIVE | −0.008 | −0.006 | −0.008 | 0.015 | 0.017 | 0.013 | −0.009 | −0.006 | −0.007 | 0.026 |
| EXAMPLE 3 | | | | | | | | | | |
| COMPARATIVE | −0.015 | −0.009 | −0.013 | 0.023 | 0.027 | 0.023 | −0.012 | −0.011 | −0.014 | 0.042 |
| EXAMPLE 4 | | | | | | | | | | |
| COMPARATIVE | −0.006 | 0.006 | 0.006 | −0.005 | 0.001 | −0.006 | 0.006 | 0.004 | −0.005 | 0.012 |
| EXAMPLE 5 | | | | | | | | | | |
| COMPARATIVE | −0.011 | −0.004 | 0.003 | 0.009 | 0.007 | 0.008 | 0.003 | −0.005 | −0.01 | 0.020 |
| EXAMPLE 6 | | | | | | | | | | |
| COMPARATIVE | −0.007 | 0.006 | 0.009 | −0.007 | −0.003 | −0.008 | 0.009 | 0.005 | −0.006 | 0.017 |
| EXAMPLE 7 | | | | | | | | | | |
| COMPARATIVE | −0.016 | −0.004 | 0.001 | 0.012 | 0.014 | 0.011 | 0.002 | −0.005 | −0.015 | 0.030 |
| EXAMPLE 8 | | | | | | | | | | |
| COMPARATIVE | −0.031 | −0.02 | −0.022 | 0.045 | 0.054 | 0.046 | −0.021 | −0.019 | −0.032 | 0.086 |
| EXAMPLE 9 | | | | | | | | | | |
| COMPARATIVE | −0.02 | −0.01 | −0.011 | 0.025 | 0.029 | 0.027 | −0.009 | −0.011 | −0.021 | 0.050 |
| EXAMPLE 10 | | | | | | | | | | |
| COMPARATIVE | −0.021 | −0.012 | −0.005 | 0.023 | 0.024 | 0.028 | 0 | −0.016 | −0.021 | 0.049 |
| EXAMPLE 11 | | | | | | | | | | |
| COMPARATIVE | 0.004 | −0.001 | −0.001 | 0.001 | −0.004 | 0 | −0.002 | −0.001 | 0.005 | 0.009 |
| EXAMPLE 12 | | | | | | | | | | |
| COMPARATIVE | 0.004 | 0.008 | 0.004 | −0.012 | −0.009 | −0.012 | 0.005 | 0.007 | 0.005 | 0.020 |
| EXAMPLE 13 | | | | | | | | | | |
| COMPARATIVE | −0.002 | 0.004 | 0.012 | −0.01 | −0.001 | −0.008 | 0.013 | 0.004 | −0.003 | 0.023 |
| EXAMPLE 14 | | | | | | | | | | |
| COMPARATIVE | −0.006 | 0.005 | 0.005 | −0.006 | 0 | −0.002 | 0.008 | 0.003 | −0.008 | 0.016 |
| EXAMPLE 15 | | | | | | | | | | |
| COMPARATIVE | −0.012 | −0.011 | −0.016 | 0.024 | 0.027 | 0.027 | −0.014 | −0.013 | −0.012 | 0.043 |
| EXAMPLE 16 | | | | | | | | | | |
| COMPARATIVE | −0.014 | −0.007 | 0.002 | 0.013 | 0.01 | 0.013 | 0.003 | −0.009 | −0.012 | 0.027 |
| EXAMPLE 17 | | | | | | | | | | |
| COMPARATIVE | −0.024 | −0.016 | −0.009 | 0.031 | 0.031 | 0.035 | −0.006 | −0.017 | −0.025 | 0.060 |
| EXAMPLE 18 | | | | | | | | | | |
| COMPARATIVE | −0.008 | 0.003 | 0.001 | 0.003 | 0.006 | 0 | 0 | 0 | −0.005 | 0.014 |
| EXAMPLE 19 | | | | | | | | | | |
| COMPARATIVE | −0.021 | −0.012 | −0.002 | 0.024 | 0.022 | 0.025 | 0 | −0.017 | −0.019 | 0.046 |
| EXAMPLE 20 | | | | | | | | | | |

In Table 2, Max-Min represents the difference between the largest flatness and smallest flatness among all measurement points that were measured. Referring to Table 2, the average value of Max-Min including Comparative Examples 1 to 20 collectively is 0.032 mm.

In Comparative Examples 1 to 20, a window member was loaded on a substrate, and an anti-reflection film was deposited on the window member at the temperature of 150° C. using the thin-film deposition apparatus. The window member on which the anti-reflection film was formed was separated from the plate and washed with water.

### [Evaluation]

### 1. Flatness Characteristics of Substrate

After depositing an anti-reflection film on a window member, the flatness of the window member was measured, and the results are shown in Tables 3 and 4 below:

TABLE 3

| (mm) | P1 | P2 | P3 | P4 | P5 | P6 | P7 | P8 | P9 | MAX − MIN |
|---|---|---|---|---|---|---|---|---|---|---|
| EXAMPLE 1 | −0.0054 | 0.0029 | −0.0147 | 0.021 | 0.0404 | 0.0169 | −0.0148 | 0.0021 | −0.0056 | 0.055 |
| EXAMPLE 2 | −0.0009 | 0.0037 | −0.0107 | 0.0113 | 0.0233 | 0.001 | −0.0107 | 0.0045 | −0.001 | 0.034 |
| EXAMPLE 3 | −0.0056 | 0.0071 | −0.0136 | 0.016 | 0.0384 | 0.0093 | −0.0136 | 0.0063 | −0.0056 | 0.052 |
| EXAMPLE 4 | −0.006 | 0.0017 | −0.0132 | 0.0193 | 0.0381 | 0.0154 | −0.0131 | 0.0015 | −0.0058 | 0.051 |
| EXAMPLE 5 | −0.009 | 0.0032 | −0.0167 | 0.0296 | 0.0516 | 0.0247 | −0.0169 | 0.0015 | −0.009 | 0.069 |
| EXAMPLE 6 | −0.0047 | 0.0017 | −0.0124 | 0.0203 | 0.0345 | 0.0142 | −0.0126 | −0.0033 | −0.0048 | 0.047 |
| EXAMPLE 7 | −0.0017 | 0.0023 | −0.0129 | 0.0183 | 0.0294 | 0.0028 | −0.0131 | 0.0022 | −0.0017 | 0.043 |
| EXAMPLE 8 | −0.0057 | 0.0017 | −0.0147 | 0.0241 | 0.0407 | 0.0165 | −0.0148 | 0 | −0.0055 | 0.056 |
| EXAMPLE 9 | −0.0073 | −0.0032 | −0.016 | 0.0334 | 0.0463 | 0.0228 | −0.0159 | −0.0012 | −0.007 | 0.062 |
| EXAMPLE 10 | −0.0046 | 0.0077 | −0.0104 | 0.0042 | 0.0298 | 0.0048 | −0.0103 | 0.0089 | −0.0044 | 0.040 |
| EXAMPLE 11 | −0.0035 | 0.0082 | −0.0101 | 0.0053 | 0.0264 | 0.0017 | −0.0097 | 0.0069 | −0.0031 | 0.037 |
| EXAMPLE 12 | −0.008 | 0.0063 | −0.0142 | 0.0211 | 0.0431 | 0.0194 | −0.0136 | 0.0035 | −0.0074 | 0.057 |
| EXAMPLE 13 | −0.0052 | 0.0028 | −0.0138 | 0.0223 | 0.0355 | 0.0162 | −0.0131 | −0.0016 | −0.0045 | 0.049 |
| EXAMPLE 14 | −0.0053 | 0.0044 | −0.0098 | 0.0129 | 0.0298 | 0.0119 | −0.0098 | 0.0016 | −0.0049 | 0.040 |
| EXAMPLE 15 | −0.0086 | 0.0019 | −0.0123 | 0.0256 | 0.0417 | 0.0225 | −0.0124 | 0.0013 | −0.0084 | 0.054 |
| EXAMPLE 16 | −0.0037 | 0.0072 | −0.0131 | 0.0153 | 0.0331 | 0.0022 | −0.0128 | 0.0074 | −0.0035 | 0.046 |
| EXAMPLE 17 | −0.0039 | 0.0079 | −0.0133 | 0.0142 | 0.0345 | 0.0038 | −0.0134 | 0.0074 | −0.0039 | 0.048 |
| EXAMPLE 18 | −0.0123 | 0.0253 | 0.0028 | 0.0004 | 0.0176 | −0.0111 | 0.0033 | 0.0118 | −0.0114 | 0.038 |
| EXAMPLE 19 | −0.0044 | 0.009 | −0.0114 | 0.0103 | 0.0313 | 0.0053 | −0.0111 | 0.0061 | −0.0044 | 0.043 |
| EXAMPLE 20 | −0.0037 | 0.0045 | −0.0116 | 0.0198 | 0.0302 | 0.004 | −0.0116 | 0.0047 | −0.0033 | 0.042 |

TABLE 4

| (mm) | P1 | P2 | P3 | P4 | P5 | P6 | P7 | P8 | P9 | MAX − MIN |
|---|---|---|---|---|---|---|---|---|---|---|
| COMPARATIVE | −0.006 | 0.031 | 0.018 | −0.038 | −0.014 | −0.034 | 0.022 | 0.029 | −0.007 | 0.069 |
| EXAMPLE 1 | | | | | | | | | | |
| COMPARATIVE | 0.068 | 0.078 | 0.051 | −0.138 | −0.12 | −0.136 | 0.049 | 0.083 | 0.065 | 0.221 |
| EXAMPLE 2 | | | | | | | | | | |
| COMPARATIVE | 0.057 | 0.069 | 0.036 | −0.115 | −0.095 | −0.114 | 0.036 | 0.07 | 0.056 | 0.185 |
| EXAMPLE 3 | | | | | | | | | | |
| COMPARATIVE | 0.053 | 0.066 | 0.032 | −0.108 | −0.087 | −0.108 | 0.031 | 0.068 | 0.052 | 0.176 |
| EXAMPLE 4 | | | | | | | | | | |
| COMPARATIVE | 0.063 | 0.08 | 0.047 | −0.134 | −0.112 | −0.135 | 0.048 | 0.078 | 0.064 | 0.215 |
| EXAMPLE 5 | | | | | | | | | | |
| COMPARATIVE | 0.055 | 0.069 | 0.045 | −0.119 | −0.1 | −0.117 | 0.047 | 0.067 | 0.055 | 0.188 |
| EXAMPLE 6 | | | | | | | | | | |
| COMPARATIVE | 0.045 | 0.086 | 0.077 | −0.146 | −0.123 | −0.146 | 0.077 | 0.085 | 0.045 | 0.232 |
| EXAMPLE 7 | | | | | | | | | | |
| COMPARATIVE | −0.003 | 0.011 | −0.019 | 0 | 0.021 | 0.001 | −0.019 | 0.012 | −0.004 | 0.040 |
| EXAMPLE 8 | | | | | | | | | | |
| COMPARATIVE | −0.026 | −0.006 | −0.039 | 0.036 | 0.065 | 0.041 | −0.036 | −0.007 | −0.028 | 0.104 |
| EXAMPLE 9 | | | | | | | | | | |
| COMPARATIVE | 0.066 | 0.073 | 0.047 | −0.127 | −0.115 | −0.131 | 0.046 | 0.071 | 0.07 | 0.204 |
| EXAMPLE 10 | | | | | | | | | | |
| COMPARATIVE | −0.011 | 0.003 | −0.023 | 0.012 | 0.032 | 0.018 | −0.022 | 0.006 | −0.015 | 0.055 |
| EXAMPLE 11 | | | | | | | | | | |
| COMPARATIVE | −0.007 | 0.008 | −0.025 | 0.009 | 0.003 | 0.009 | −0.023 | 0.003 | −0.004 | 0.034 |
| EXAMPLE 12 | | | | | | | | | | |
| COMPARATIVE | 0.068 | 0.083 | 0.051 | −0.143 | −0.121 | −0.141 | 0.051 | 0.084 | 0.067 | 0.227 |
| EXAMPLE 13 | | | | | | | | | | |
| COMPARATIVE | −0.05 | −0.039 | −0.065 | 0.097 | 0.114 | 0.096 | −0.066 | −0.036 | −0.051 | 0.180 |
| EXAMPLE 14 | | | | | | | | | | |
| COMPARATIVE | 0.053 | 0.03 | 0.058 | −0.087 | −0.11 | −0.085 | 0.059 | 0.031 | 0.051 | 0.169 |
| EXAMPLE 15 | | | | | | | | | | |
| COMPARATIVE | −0.065 | −0.052 | −0.085 | 0.126 | 0.149 | 0.13 | −0.086 | −0.048 | −0.069 | 0.235 |
| EXAMPLE 16 | | | | | | | | | | |
| COMPARATIVE | 0.054 | 0.043 | 0.066 | −0.102 | −0.12 | −0.104 | 0.066 | 0.042 | 0.055 | 0.186 |
| EXAMPLE 17 | | | | | | | | | | |
| COMPARATIVE | 0.047 | 0.06 | 0.033 | −0.101 | −0.082 | −0.098 | 0.034 | 0.061 | 0.045 | 0.162 |
| EXAMPLE 18 | | | | | | | | | | |
| COMPARATIVE | 0.062 | 0.08 | 0.045 | −0.131 | −0.109 | −0.134 | 0.043 | 0.081 | 0.063 | 0.215 |
| EXAMPLE 19 | | | | | | | | | | |
| COMPARATIVE | 0.051 | 0.065 | 0.041 | −0.111 | −0.094 | −0.109 | 0.044 | 0.062 | 0.052 | 0.176 |
| EXAMPLE 20 | | | | | | | | | | |

In Table 3, the average value of Max-Min including Examples 1 to 20 collectively is 0.048 mm. In Table 4, the average value of Max-Min including Comparative Examples 1 to 20 collectively is 0.164 mm.

It can be seen from the results shown in Tables 3 and 4 that all of the Max-Min values among Examples 1 to 20 are equal to or less than 0.1 mm. In contrast, it can be seen that the average Max-Min including Comparative Examples 1 to 20 collectively is equal to or greater than 0.1 mm, and that for Comparative Example 16, the Max-Min value is 0.235 mm.

It can be seen that there is almost no difference in the flatness of the window member before and after the deposition of the deposition material in Examples 1 to 20 where the separator was formed on the window member. In contrast, it can be seen that the flatness of the window member changed after the deposition of the deposition material in Comparative Examples 1 to 20 where the window member was directly loaded onto the plate without the separator on the window member and the deposition material was deposited on the window member. This means that warping occurred in the window member that was in contact with the plate in a high-temperature environment.

In summary, by forming the separator on the window member, it is possible to prevent and otherwise mitigate warping of the window member when the deposition material is deposited in a high-temperature environment.

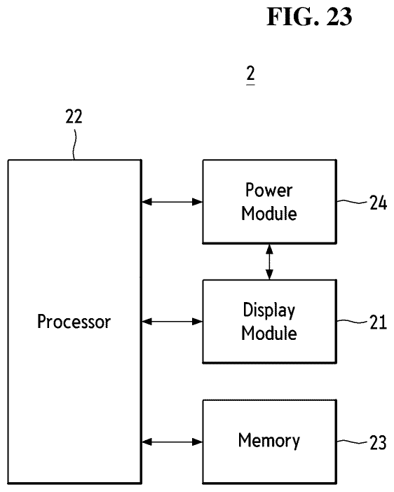

FIG. 23 is a block diagram of an electronic device according to an embodiment of the present disclosure. Referring to FIG. 23, an electronic device 2 according to an embodiment of the present disclosure may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 2.

At least one of the elements of the electronic device 2 described above may be included in the display device 1 according to some embodiments of the present disclosure. In addition, some of the individual modules functioning as a single module may be included in the display device 1 while some others may be provided separately from the display device 1. For example, the display device 1 may include the display module 21, and the processor 22, the memory 23 and the power module 24 may be provided as other devices inside the electronic device 2 separate from the display device 1.

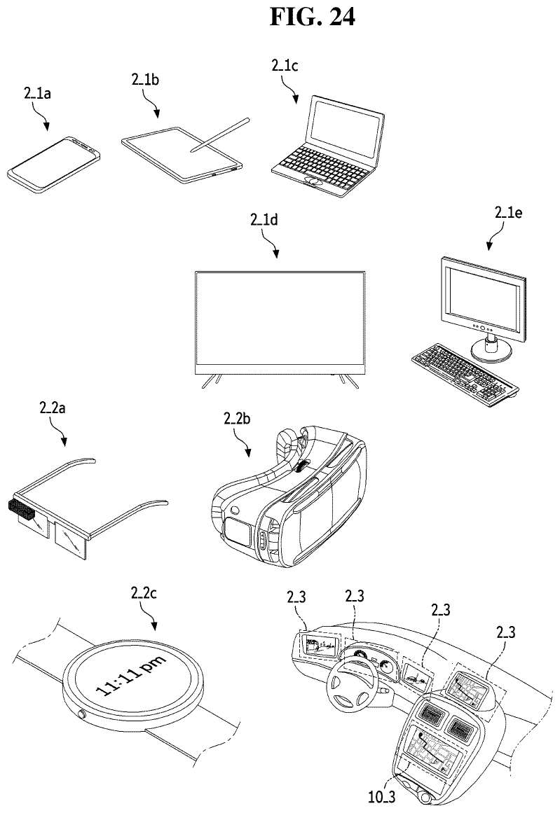

FIG. 24 shows electronic devices according to a variety of embodiments of the present disclosure. Referring to FIG. 24, a variety of electronic devices 2 employing the display devices according to embodiments of the present disclosure may include not only electronic devices for display images such as a smart phone 2_1a, a tablet PC 2_1b, a laptop computer 2_1c, a TV 2_1d and a desktop monitor 2_1e, but may also include wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

Although the embodiments of the present disclosure have been described with reference to the attached drawings, those skilled in the art will understand that the present disclosure can be implemented in other specific forms without changing the technical idea or essential features of the present disclosure. Therefore, it should be understood that the embodiments described above are exemplary in all respects and not restrictive.

What is claimed is:

1. A method for fabricating a display device, the method comprising:
forming a separator on a first surface of a substrate;
loading the substrate on a plate such that the plate faces the first surface of the substrate;
depositing a deposition material on a second surface of the substrate, the second surface being opposite the first surface;
separating the substrate from the plate; and
cleaning the substrate to remove the separator from the substrate,
wherein the separator comprises a polymer resin having carboxyl functional groups or hydroxyl functional groups.

2. The method of claim 1, wherein a thickness of the separator is 20% or more of a thickness of the substrate.

3. The method of claim 2, wherein the thickness of the separator is equal to or greater than 100 μm.

4. The method of claim 1, wherein a surface area of the separator is equal to or less than 50% of a surface area of the first surface of the substrate.

5. The method of claim 1, wherein the depositing is carried out at a temperature of 100 degrees Celsius or higher.

6. The method of claim 1, wherein the forming of the separator further comprises:
spraying a separator ink on the first surface of the substrate; and
curing the separator ink with ultraviolet rays to form the separator.

7. The method of claim 6, wherein the steps of spraying the separator ink and curing the separator ink with ultraviolet rays are repeated until a thickness of the separator becomes equal to or greater than at least 20% of a thickness of the substrate.

8. The method of claim 1, wherein the substrate is a window member of the display device, and the deposition material is an anti-reflection film of the display device or an anti-fingerprint film of the display device.

9. The method of claim 1, wherein the polymer resin having the carboxyl functional groups comprises at least one of: (meth)acrylic acid, 2-(meth)acryloyloxy acetic acid, 3-(meth)acryloyloxy propyl acid, 4-(meth)acryloyloxy butyric acid, an acrylic acid dimer, itaconic acid and maleic acid.

10. The method of claim 1, wherein the polymer resin having the hydroxyl functional groups comprises at least one of: 2-hydroxyethyl (meth)acrylate, 3-hydroxypropyl (meth)acrylate, 4-hydroxybutyl (meth)acrylate, and 6-hydroxyhexyl (meth)acrylate.

11. The method of claim 1, wherein the cleaning is performed using at least one of water and an alkaline solution.

12. The method of claim 1, further comprising: prior to the forming of the separator, forming a black mark on the first surface of the substrate adjacent to an edge of the first surface of the substrate,
wherein the separator is formed on the black mark.

13. The method of claim 1, wherein the forming of the separator further comprises:
forming a first separator on the first surface of the substrate; and
forming a second separator on the first surface such that the second separator is spaced apart from the first separator.

14. The method of claim 1, wherein the forming of the separator further comprises: simultaneously forming a first separator and a second separator spaced apart from the first separator on the first surface of the substrate.

15. The method of claim 13, wherein the forming of the first separator and the second separator further comprises:
forming the first separator such that the first separator is located adjacent to an edge on a first side of the substrate on the first surface of the substrate and extends in a first direction along the first side; and
forming the second separator such that the second separator is located adjacent to an edge on a second side of the substrate on the first surface of the substrate, the second side being opposite to the first side of the substrate, and the second separator extending in the first direction along the second side,
wherein the first separator is parallel to the second separator.

16. The method of claim 1, wherein the separator is formed on the first surface of the substrate adjacent to an edge of the first surface of the substrate.

17. The method of claim 13, wherein the first separator is formed adjacent to an edge on the first surface of the substrate and the second separator is formed further from the edge on the first surface than the first separator such that a minimum distance between the first separator and the edge is less than a minimum distance between the second separator and the edge.

18. An electronic device comprising:
a display module configured to provide images; and
a processor configured to transmit an image data signal to the display module,
wherein the display module is fabricated by a method comprising:
forming a separator on a first surface of a substrate;
loading the substrate on a plate such that the plate faces the first surface of the substrate;
depositing a deposition material on a second surface of the substrate, the second surface being opposite the first surface;
separating the substrate from the plate; and
cleaning the substrate to remove the separator from the substrate, and
wherein the separator comprises a polymer resin having carboxyl groups or hydroxyl functional groups.

19. The electronic device of claim 18, wherein a thickness of the separator is 20% or more of a thickness of the substrate.

20. The electronic device claim 18, wherein the substrate is a window member of the display module, and the deposition material is an anti-reflection film of the display module or an anti-fingerprint film of the display module.
